(19) United States
(12) Patent Application Publication
(10) Pub. No.: US 2026/0235667 A1
(43) Pub. Date: Aug. 13, 2026

(54) SIGNAL ACQUISITION DIAGNOSTICS

(71) Applicant: Allegro MicroSystems, LLC, Manchester, NH (US)

(72) Inventors: Andrea Foletto, Andorno Micca (IT); James McIntosh, East Lothian (GB); Ignazio De Guglielmi, Edinburgh (GB)

(73) Assignee: Allegro MicroSystems, LLC, Manchester, NH (US)

(21) Appl. No.: 19/051,536

(22) Filed: Feb. 12, 2025

(51) Int. Cl. G01R 31/28; G01R 31/302; H03M 1/10

(52) U.S. Cl. CPC G01R 31/2896; G01R 31/302; H03M 1/1071

(57) ABSTRACT

Methods and apparatus for a signal acquisition system having a normal mode diagnostic modes. In embodiments, a method includes performing offset cancellation by cancelling the first input signal during an offset diagnostic mode, comparing an output of the amplifier to a first threshold in response to cancelling the first signal, and generating an offset fault when the first threshold is exceeded. In an injection diagnostic mode, a method includes injecting a second signal into the amplifier, combining an output from the amplifier during the injection of the second signal and a reconstructed signal generated from the first signal to generate a combiner output signal, comparing the combiner output signal to a second threshold, and examining a result of the comparison of the combiner output signal and the second threshold to detect a circuit fault.

### BACKGROUND

As is known in the art, it is desirable to detect circuit malfunctions, particularly for faults that may result in unsafe conditions. Various industries have established standards to achieve safe product operation. For example, ASIL (Automotive Safety Integrity level) standards include risk classification, such as ASIL-A, ASIL-B, ASIL-C, and ASIL-D, for automobiles. The highest integrity requirements are defined in ASIL-D. It can be challenging to meet such standards.

### SUMMARY

Example embodiments of the disclosure provide methods and apparatus for integrated circuit packages having signal acquisition monitoring. In embodiments, signal acquisition monitoring includes detecting malfunctions that can lead to unsafe operation. In some embodiments, signal monitoring may include redundancy for providing ASIL functionality.

In embodiments, an IC includes diagnostics for signal acquisition in a circuit having a gain stage and/or preconditioning stage, and an ADC to process the data in order to achieve ASIL-D coverage without need of redundant circuitry for minimizing area and cost. While example embodiments of the disclosure may be shown and described in conjunction with a gate driver IC package, it is understood that embodiments of the disclosure as claimed are applicable to ICs in general in which signal acquisition diagnostics are desirable.

In one aspect, a method comprises: acquiring a first signal during normal mode with an amplifier for a magnetic field sensor having magnetic field sensing elements; performing offset cancellation by cancelling the first input signal during a diagnostic mode; comparing an output of the amplifier to a first threshold in response to cancelling the first signal and generating an offset fault when the first threshold is exceeded; injecting a second signal into the amplifier during the diagnostic mode; combining an output from the amplifier during the injection of the second signal and a reconstructed signal generated from the first signal to generate a combiner output signal; comparing the combiner output signal to a second threshold; and examining a result of the comparison of the combiner output signal and the second threshold to detect a circuit fault.

A method can further include one or more of the following features: the first threshold includes a minimum value and a maximum value, employing a sample and hold circuit at the output of the amplifier, reconstructing the output from the first signal using a filter, the filter comprises an IIR filter, the second threshold includes a minimum value and a maximum value, the minimum and maximum values correspond to an ideal value for a diagnostic pulse, the amplifier forms part of a gate driver IC package, the gate driver IC package is configured to drive at least one high power FET, adjusting the second signal to exercise an ADC over its dynamic range, the reconstructed signal is interpolated, and/or the amplifier is configured in a chopping configuration.

In another aspect, a system comprises: an amplifier configured to acquire a first signal during normal mode for a magnetic field sensor having magnetic field sensing elements; and circuitry configured to: perform offset cancellation by cancelling the first input signal during a diagnostic mode; compare an output of the amplifier to a first threshold in response to cancelling the first signal and generating an offset fault when the first threshold is exceeded; inject a second signal into the amplifier during the diagnostic mode; combine an output from the amplifier during the injection of the second signal and a reconstructed signal generated from the first signal to generate a combiner output signal; compare the combiner output signal to a second threshold; and examine a result of the comparison of the combiner output signal and the second threshold to detect a circuit fault.

A system can further include one or more of the following features: the first threshold includes a minimum value and a maximum value, employing a sample and hold circuit at the output of the amplifier, reconstructing the output from the first signal using a filter, the filter comprises an IIR filter, the second threshold includes a minimum value and a maximum value, the minimum and maximum values correspond to an ideal value for a diagnostic pulse, the amplifier forms part of a gate driver IC package, the gate driver IC package is configured to drive at least one high power FET, adjusting the second signal to exercise an ADC over its dynamic range, the reconstructed signal is interpolated, and/or the amplifier is configured in a chopping configuration.

### BRIEF DESCRIPTION OF THE DRAWINGS

The foregoing features of the disclosure, as well as the disclosure itself may be more fully understood from the following detailed description of the drawings, in which:

FIG. 1 shows an example gate driver IC package having signal acquisition diagnostics in accordance with illustrative embodiments of the disclosure;

FIG. 2 shows an example circuit implementation of a portion of signal acquisition diagnostics in accordance with illustrative embodiments of the disclosure;

FIG. 3 shows a graphical representation of plots for offset cancellation and diagnostic signal injection;

FIG. 4 shows signals over time for signal acquisition and offset cancellation and diagnostic signal injection;

FIGS. 5A and 5B are waveform diagrams for LSBs of a signal and LSB error during signal acquisition and offset cancellation and diagnostic signal injection;

FIG. 6 is a flow diagram of an example sequence of steps for providing signal acquisition and offset cancellation and diagnostic signal injection; and

FIG. 7 is schematic diagram of an example computer/microprocessor that can perform at least a portion of the processing described herein.

### DETAILED DESCRIPTION

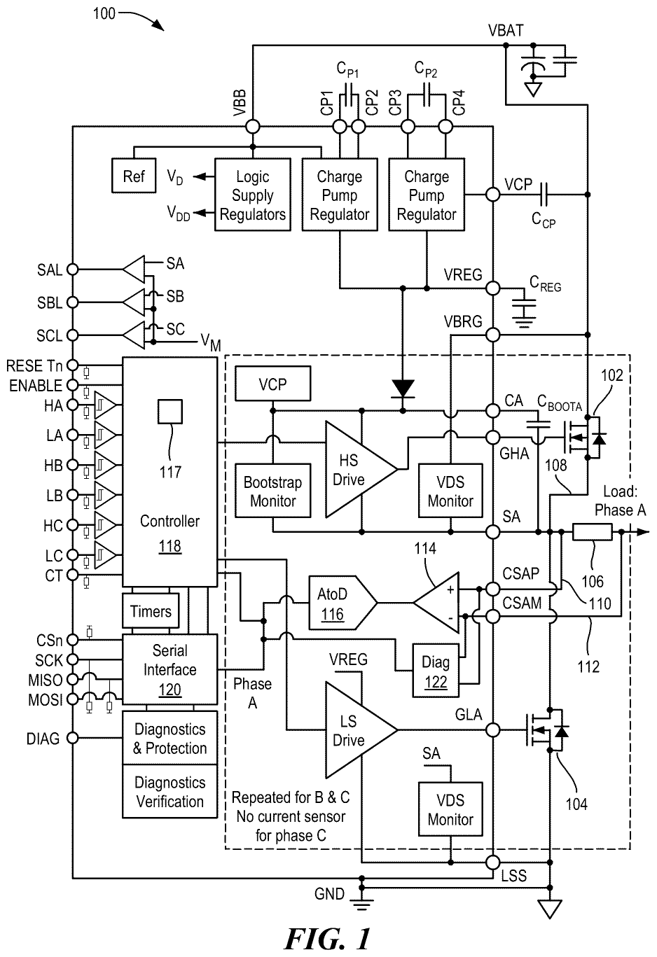

FIG. 1 shows an example IC package 100 including signal acquisition with diagnostics having offset cancellation and pulse injection in accordance with illustrative embodiments of the disclosure. In one embodiment, the IC package 100 comprises one or more gate drivers for driving external HIGH and LOW side power switches 102, 104 with respective gate drive signals GHA, GLA, in manner well known in the art.

In an example embodiment, an impedance element 106, such as a shunt resistor, is coupled to a node 108 between the power switches 102, 104 and a load such as a motor. First and second sense signals 110, 112 sense the voltage across the impedance element 106 to measure current. The first and second sense signals 110, 112 are provided to a sense amplifier 114 the output of which is coupled to an analog-to-digital converter (ADC) 116. In embodiments, the ADC 116 output is processed by a processor 117 within a controller 118 and sent to a serial interface 120 for transmission to an MCU. In some embodiments, a single module can comprise processor 117, diagnostic module 122, etc. In embodiments, the amplifier can integrate a chopping technique or similar for removing undesirable DC offset voltages. U.S. Pat. No. 10,444,299, which is incorporated herein by reference, discusses example circuitry for removing DC offsets generated in the magnetic field sensing elements, such as Hall effect elements.

A diagnostic module 122 injects diagnostic pulses on top of the sense signals 110, 112 during normal operation and processes the output of the ADC 116 output. As described more fully below, the diagnostic module 122 controls the pulse injection in accordance with illustrative embodiments of the disclosure and elaborates the signal at the output of the ADC 116.

While example embodiments of the disclosure are shown and described in conjunction with a gate driver IC, it is understood that embodiments of the disclosure are applicable to ICs in general in which single or multiple current acquisition diagnostics are desirable.

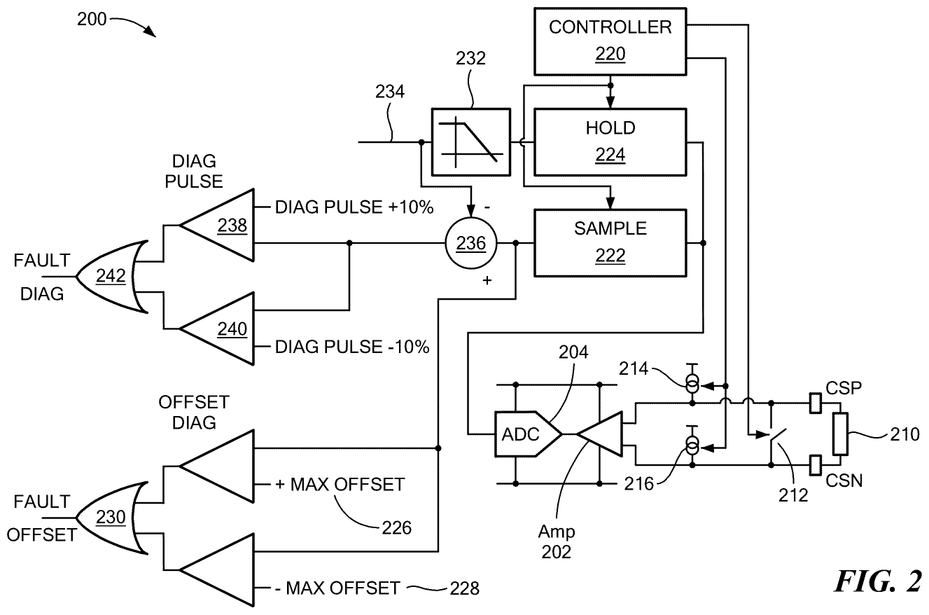

FIG. 2 shows an example circuit implementation 200 for signal acquisition, such as in a current sensor 210, having an amplification or signal conditioning stage 202, which can comprise an amplifier, and an optional ADC 204 to covert the signal from the analog domain.

In the illustrated embodiment, first and second sense signals 206, 208 are coupled across a resistor 210 to sense the current flowing and provide it to the amplifier 202 the output of which is coupled to the ADC 204. A diagnostic switch 212 is coupled across the amplifier inputs, which comprise the first and second sense signals 206,208. When the switch 212 is closed, the inputs of the amplifier 202 are shorted together in order to diagnose the offset introduced by the signal acquisition path 202 and 204.

A first signal injector 214 is coupled to the first input of the amplifier 202 and an optional second signal injector 216 is coupled to the second input of the amplifier in order to inject a diagnostic pulse or signal on top of any signal going to the amplifier 202 with arbitrary polarity. As described more fully below, the injected signal can be removed later for diagnostic signal processing.

In embodiments, the offset diagnostic and diagnostic signal injection modes are operated in an example sequence at different times. During offset diagnostic mode, any input signal on the first and second sense signals 206, 208 is cancelled when the switch is closed. It is understood that other suitable techniques can be used to cancel the input signal to the amplifier. During this phase, the output of the signal acquisition at the ADC 204 output is monitored. In embodiments, the ADC output value is compared against a predefined threshold. If the offset is higher than expected, a fault can be generated.

In embodiments, a control module 220, such as the diagnostic module 122 in FIG. 1, can include circuitry and/or microprocessor to control the diagnostic modes and perform the comparison of the ADC output and generate and transmit a fault as appropriate. In example embodiments, the control module 220 operates in two modes. A first mode can force zero offset. A sample 222 and hold 224 of the ADC 204 output can be compared with max and min offsets 226, 228. If either the max or min values are exceeded, a Fault Offset signal 230 can be activated. During this time the signal at the output of the ADC 204 is hold 224 for signal reconstruction by a filter 232, which output a reconstructed signal 234.

In embodiments, the system samples data for offset and holds the “previous” value for the signal reconstruction thereby masking the offset signal. In embodiments, previous or last signal is added before applying the offset. When the offset or diagnostic is not injected the hold circuit operates as a pass through and the current info is passed away.

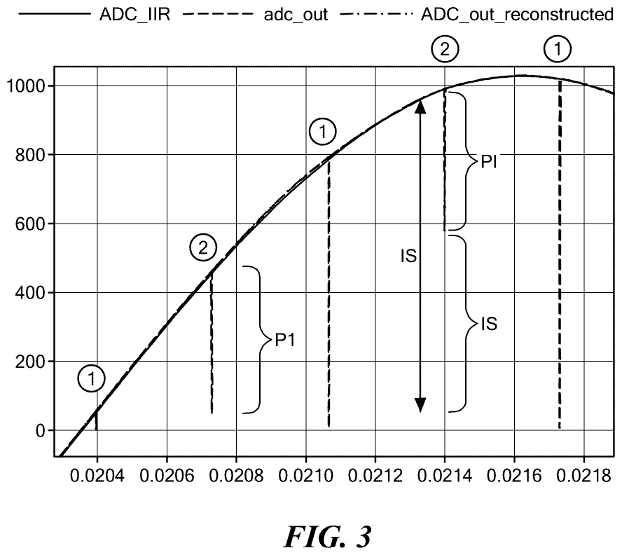

In a second mode, the control module 220 forces a diagnostic pulse (see FIG. 3). The ADC 204 output is sampled 222 and subtracted by a signal combiner 236 from the reconstructed signal 234. In embodiments, the combiner 236 can receive the signal of the hold block, which may be last available before injection the diagnostic pulse or it can be a combination of the signal before and after the diagnostic pulse (like average or interpolation). In other embodiments, the ADC output is subtracted from the signal prior to the hold. The output of the signal combiner 236 is compared to an ideal diagnostic pulse to determine if a fault is present. In the illustrated embodiment, the output of the signal combiner 236 is compared 238 to +10% of an ideal diagnostic pulse and compared 240 to −10% of an ideal diagnostic pulse. It is understood that any practical percentage or other metric can be used to meet the needs of a particular application. If the plus or minus thresholds are exceeded, a diagnostic pulse fault signal 242 can be activated. During this time, the signal at the output of the ADC 204 is hold 224 and the filter 232 reconstructs it.

In the illustrated embodiment, the filter 232 comprises an IIR filter coupled to the output of the ADC 204 via a hold 224 circuit. In some embodiments, an output of the ADC is coupled directly to a control module 220, which may control over operation of the circuit modes and receive and generate signals needed for normal and diagnostic mode functionality.

In embodiments, the diagnostic signal is selected to mee the needs of a particular application. In some embodiments, the diagnostic signal can be controlled to, for example, exercise the ADC 204 over its dynamic range over some number of cycles of diagnostic cycles interleaved within normal operation. The diagnostic signal from different injections can be used to have more accurate and robust diagnostics, for example averaging the results or doing a vote scheme.

FIG. 3 shows an example plot of offset cancellation indicated by circled ones and diagnostic signal injections are indicated by circles twos. As can be seen, injected diagnostic pulses PI on top of the input signal IS can exercise the full range of the ADC 204. This allows detection of nonlinearity and gain errors generated by the amplifier 202 or by the ADC 204.

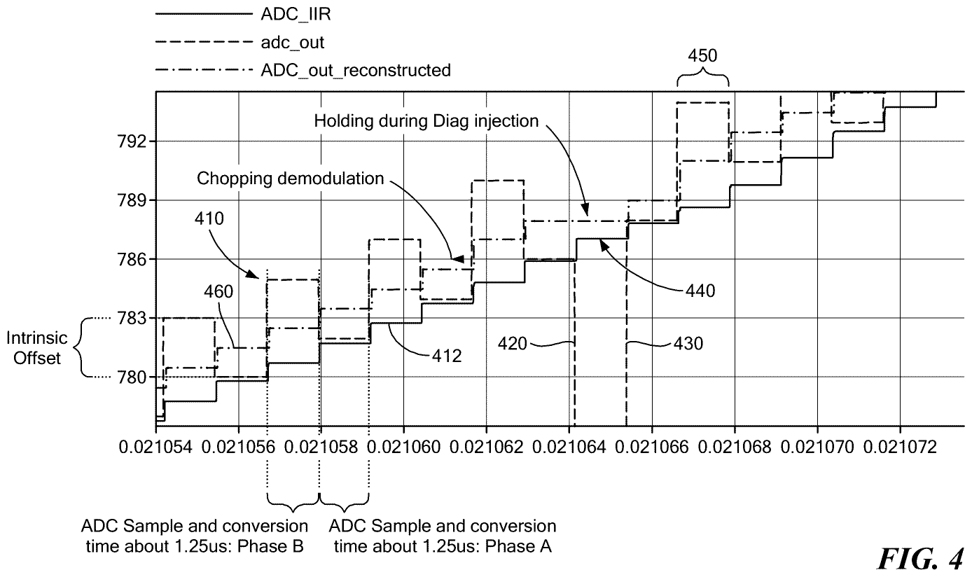

FIG. 4 shows additional detail of various signals over time during normal signal acquisition and diagnostic operations of offset cancellation and pulse injection provided in the example circuit implementation of FIG. 2. In the example waveforms, the input signal for acquisition, e.g., the signal on CSAP and CSAM in FIG. 1, is sinusoidal and here is reported only a small section. In the illustrated embodiment, a scenario with offset and chopping technique on the sense amplifier, such as the circuit 202 of FIG. 2 is shown. As noted above, chopping is a well-known technique for reducing DC offset error. The input of the sense amplifier with offset 410 compensated through chopping techniques is converted in the digital domain generating signal 460 in FIG. 4. Offset 410 is the signal when a signal with offset is passed through a chopping technique and 460 is the signal reconstructed after chopping.

During offset cancellation diagnostic mode at the falling edge 420 of the pulse, e.g., shorting the amplifier inputs, the output of the ADC 410 goes to zero if no offset error is present. A comparator module, such as the comparator 234 of FIG. 2, can be used to verify that the ADC output goes to zero, e.g., is within min and max thresholds.

When a diagnostic pulse is injected, the output of the ADC reports the input signal plus the diagnostic pulse.

The duration of the diagnostic pulse is one clock long, e.g., between 420 and 430. The longer step indicates the signal holding and signal 440 is the interpolated or reconstructed signal. As explained above, sampled pulse 222 during diagnostic is subtracted to from 440 to generate the diagnostic pulse amplitude that will be compared against predefined threshold. The difference between the interpolated ADC value 440 using previous and next sample can be used as baseline to be subtracted from the sample/hold signal from the amplifier in order to extract the diagnostic pulse, as described above. The diagnostic pulse, which is the result of the subtraction as described above, is then compared against predefined thresholds, e.g., +−10 % of a selected value, in order to detect an amplitude change that indicates a fault in the system.

During the diagnostic pulse injection the output of the ADC can be held and interpolated through a filter, such as filter 232 in FIG. 2, to be used as a signal to the ECU (engine control unit).

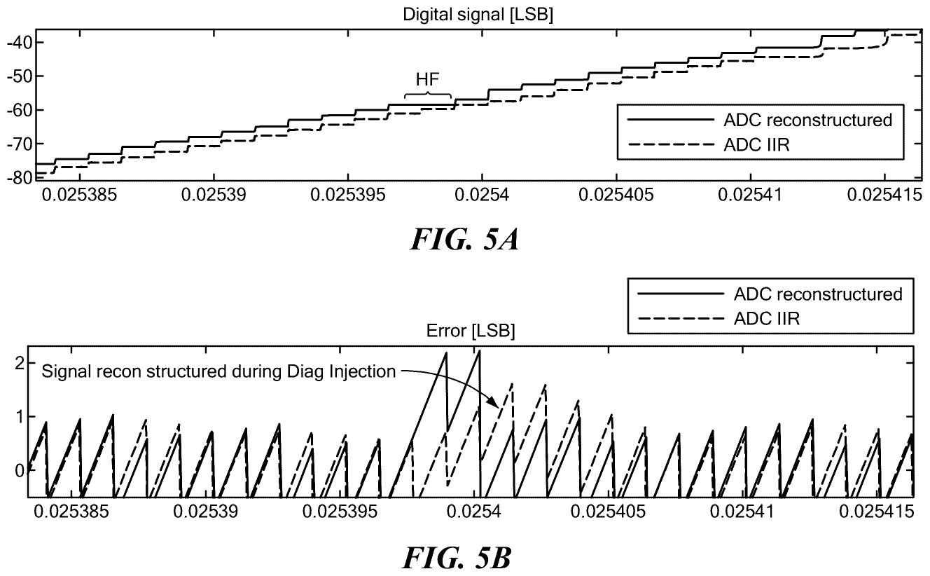

While the reconstructed signal allows use of the acquisition signal during normal operation, performing diagnostics on signal acquisition has minimal impact on normal operation. In embodiments, offset cancellation and diagnostic pulse injection is one clock cycle long to minimize the impact on the signal accuracy, as demonstrated in FIGS. 5A and 5B below.

FIG. 5A shows the reconstructed ADC output 234 (FIG. 2) in LSB and the ADC output. As can be seen, around time 0.0254 diagnostics are performed, such as offset cancellation and/or signal injection, the ADC output is hold to its previous value and the signal reconstructed through the filter.

FIG. 5B shows the error in LSB for the ADC output when holding its state during diagnostic and the reconstructed signal through the filtered (IIR) ADC output. As can be seen, the error versus an ideal signal is divided by almost a factor of two after interpolation through filter compared to the ADC output when the signal was kept in hold.

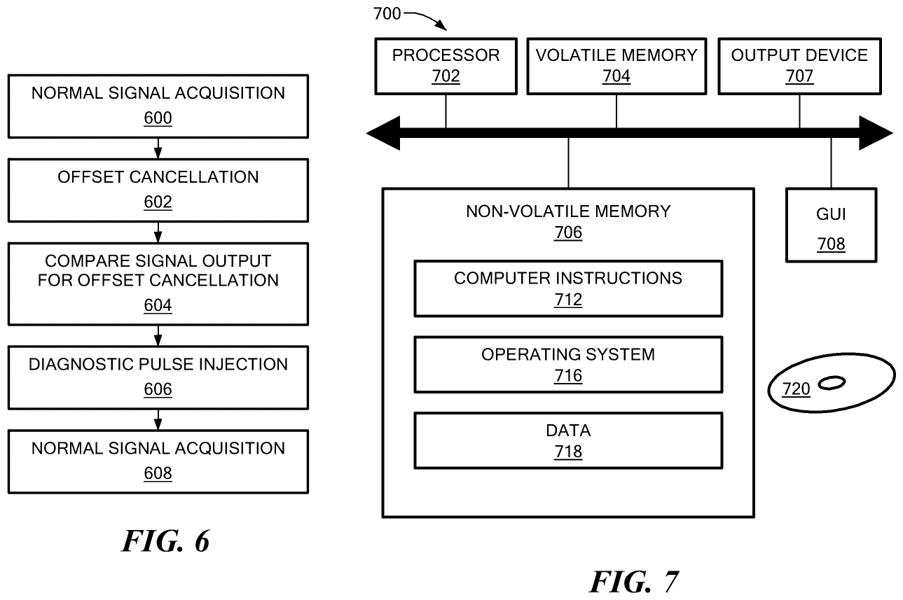

FIG. 6 shows an example sequence of steps for signal acquisition diagnostics in accordance with example embodiments of the disclosure. In step 600, signal acquisition is performed in a normal mode. For example, the current across a load resistor can be provided to an amplifier in a chopping configuration and output to an ADC. In step 602, at a given time, offset cancellation is performed, such as by activating a switch to short the inputs of the amplifier. In step 604, the ADC output is compared to a threshold to verify proper operation of the ADC in response to the short circuit. In step 606, a diagnostic pulse is injected on top of the acquisition signal. In embodiments, between steps 604 and 606 the current is measured normally. The diagnostic pulse can be configured to exercise a dynamic range of the ADC and verify proper operation. In step 608, normal signal acquisition mode is re-entered.

FIG. 7 shows an exemplary computer 700 that can perform at least part of the processing described herein. For example, the computer 700 can perform control normal and diagnostic modes and generate signals for sensor operation, as described above. The computer 700 includes a processor 702, a volatile memory 704, a non-volatile memory 706 (e.g., hard disk), an output device 707 and a graphical user interface (GUI) 708 (e.g., a mouse, a keyboard, a display, for example). The non-volatile memory 706 stores computer instructions 712, an operating system 716 and data 718. In one example, the computer instructions 712 are executed by the processor 702 out of volatile memory 704. In one embodiment, an article 720 comprises non-transitory computer-readable instructions.

Processing may be implemented in hardware, software, or a combination of the two. Processing may be implemented in computer programs executed on programmable computers/machines that each includes a processor, a storage medium or other article of manufacture that is readable by the processor (including volatile and non-volatile memory and/or storage elements), at least one input device, and one or more output devices. Program code may be applied to data entered using an input device to perform processing and to generate output information.

The system can perform processing, at least in part, via a computer program product, (e.g., in a machine-readable storage device), for execution by, or to control the operation of, data processing apparatus (e.g., a programmable processor, a computer, or multiple computers). Each such program may be implemented in a high-level procedural or object-oriented programming language to communicate with a computer system. However, the programs may be implemented in assembly or machine language. The language may be a compiled or an interpreted language and it may be deployed in any form, including as a stand-alone program or as a module, component, subroutine, or other unit suitable for use in a computing environment. A computer program may be deployed to be executed on one computer or on multiple computers at one site or distributed across multiple sites and interconnected by a communication network. A computer program may be stored on a storage medium or device (e.g., CD-ROM, hard disk, or magnetic diskette) that is readable by a general or special purpose programmable computer for configuring and operating the computer when the storage medium or device is read by the computer.

Processing may also be implemented as a machine-readable storage medium, configured with a computer program, where upon execution, instructions in the computer program cause the computer to operate.

Processing may be performed by one or more programmable embedded processors executing one or more computer programs to perform the functions of the system. All or part of the system may be implemented as, special purpose logic circuitry (e.g., an FPGA (field programmable gate array) and/or an ASIC (application-specific integrated circuit)).

Having described exemplary embodiments of the disclosure, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A method, comprising:
acquiring a first signal during normal mode with an amplifier for a magnetic field sensor having magnetic field sensing elements;
performing offset cancellation by cancelling the first input signal during a diagnostic mode;
comparing an output of the amplifier to a first threshold in response to cancelling the first signal and generating an offset fault when the first threshold is exceeded;
injecting a second signal into the amplifier during the diagnostic mode;
combining an output from the amplifier during the injection of the second signal and a reconstructed signal generated from the first signal to generate a combiner output signal;
comparing the combiner output signal to a second threshold; and
examining a result of the comparison of the combiner output signal and the second threshold to detect a circuit fault.

2. The method according to claim 1, wherein the first threshold includes a minimum value and a maximum value.

3. The method according to claim 1, further including employing a sample and hold circuit at the output of the amplifier.

4. The method according to claim 1, further including reconstructing the output from the first signal using a filter.

5. The method according to claim 4, wherein the filter comprises an IIR filter.

6. The method according to claim 1, wherein the second threshold includes a minimum value and a maximum value.

7. The method according to claim 6, wherein the minimum and maximum values correspond to an ideal value for a diagnostic pulse.

8. The method according to claim 1, wherein the amplifier forms part of a gate driver IC package.

9. The method according to claim 8, wherein the gate driver IC package is configured to drive at least one high power FET.

10. The method according to claim 1, further including adjusting the second signal to exercise an ADC over its dynamic range.

11. The method according to claim 1, wherein the reconstructed signal is interpolated.

12. The method according to claim 1, wherein the amplifier is configured in a chopping configuration.

13. A system, comprising:
an amplifier configured to acquire a first signal during normal mode for a magnetic field sensor having magnetic field sensing elements; and
circuitry configured to:
perform offset cancellation by cancelling the first input signal during a diagnostic mode;
compare an output of the amplifier to a first threshold in response to cancelling the first signal and generating an offset fault when the first threshold is exceeded;
inject a second signal into the amplifier during the diagnostic mode;
combine an output from the amplifier during the injection of the second signal and a reconstructed signal generated from the first signal to generate a combiner output signal;
compare the combiner output signal to a second threshold; and
examine a result of the comparison of the combiner output signal and the second threshold to detect a circuit fault.

14. The system according to claim 13, wherein the first threshold includes a minimum value and a maximum value.

15. The system according to claim 13, further including a sample and hold circuit at the output of the amplifier.

16. The system according to claim 1, wherein the circuitry is further configured to reconstruct the output from the first signal using a filter.

17. The system according to claim 13, wherein the amplifier forms part of a gate driver IC package.

18. The system according to claim 13, wherein the circuitry is further configured to adjust the second signal to exercise an ADC over its dynamic range.

19. The system according to claim 13, wherein the reconstructed signal is interpolated.

20. The system according to claim 13, wherein the amplifier is configured in a chopping configuration.
